(19) United States
(12) Patent Application Publication
(10) Pub. No.: US 2021/0184434 A1
(43) Pub. Date: Jun. 17, 2021

(54) LIGHT-EMITTING DEVICE

(71) Applicant: Sony Semiconductor Solutions Corporation, Kanagawa (JP)

(72) Inventors: Hideki WATANABE, Kumamoto (JP); Yuusuke NAKAYAMA, Kumamoto (JP)

(21) Appl. No.: 17/270,982

(22) PCT Filed: Aug. 5, 2019
(86) PCT No.: PCT/JP2019/030676

§ 371 Date: Feb. 24, 2021

(30) Foreign Application Priority Data
Aug. 24, 2018 (JP) 2018-157117

(51) Int. Cl. H01S 5/20; H01S 5/34

(52) U.S. Cl. CPC H01S 5/20; H01S 5/34

(57) ABSTRACT

A light-emitting device according to an embodiment of the present technology includes a first composition changing layer, an interlayer, and a second composition changing layer. The first composition changing layer has a composition continuously changed at a first change rate from a first position to a second position in a thickness direction of the light-emitting device. The interlayer is formed between the second position and a third position in the thickness direction, the interlayer having a composition identical to a composition of the first composition changing layer at the second position. The second composition changing layer has a composition continuously changed at a second change rate from the third position to a fourth position in the thickness direction, the second composition changing layer having, at the third position, a composition identical to the composition of the interlayer.

### TECHNICAL FIELD

The present technology relates to a light-emitting device such as a semiconductor laser.

### BACKGROUND ART

The semiconductor laser device disclosed in Patent Literature 1 includes a lower optical confinement layer and an upper optical confinement layer that are each formed such that the composition is continuously changed in a thickness direction of the semiconductor laser device. Further, an interlayer having a composition of a constant bandgap wavelength is formed between the lower optical confinement layer and a lower cladding layer. Furthermore, the interlayer having the same composition is also formed between the upper optical confinement layer and an upper cladding layer. This results in being able to form a stable crystal layer even in a region with a less flow rate of delivery of a component element, and thus to improve the efficiency in carrier injection and the crystallinity (for example, paragraphs [0034], [0035], and [0051] of the specification, and FIG. 1 in Patent Literature 1).

### CITATION LIST

### Patent Literature

Patent Literature 1: Japanese Patent Application Laid-open No. 2003-174236

### DISCLOSURE OF INVENTION

### Technical Problem

There is a need for a technology that makes it possible to test a light-emitting device non-destructively and efficiently when a layer having a composition continuously changed in the thickness direction is formed in the light-emitting device, such as the case of the semiconductor laser device disclosed in Patent Literature 1.

In view of the circumstances described above, an object of the present technology is to provide a light-emitting device that makes it possible to perform a non-destructive, efficient test.

### Solution to Problem

In order to achieve the object described above, a light-emitting device according to an embodiment of the present technology includes a first composition changing layer, an interlayer, and a second composition changing layer.

The first composition changing layer has a composition continuously changed at a first change rate from a first position to a second position in a thickness direction of the light-emitting device.

The interlayer is formed between the second position and a third position in the thickness direction, the interlayer having a composition identical to a composition of the first composition changing layer at the second position.

The second composition changing layer has a composition continuously changed at a second change rate from the third position to a fourth position in the thickness direction, the second composition changing layer having, at the third position, a composition identical to the composition of the interlayer.

In this light-emitting device, an interlayer in which a composition is constant is formed between the first position and the fourth position in the thickness direction. Consequently, for example, the use of X-ray diffraction or the like makes it possible to test the light-emitting device non-destructively and efficiently.

The first change rate may be identical to the second change rate.

The light-emitting device may be configured as a semiconductor laser device.

The first composition changing layer, the interlayer, and the second composition changing layer may form a guide layer.

The interlayer may have a thickness of not less than 20 nm.

When the first position is represented by 0 and the fourth position is represented by 1, the interlayer may be formed in a range of from 0.1 to 0.9.

The first composition changing layer, the interlayer, and the second composition changing layer may form a compositional gradient layer having a constant composition between the second position and the third position.

The first composition changing layer, the interlayer, and the second composition changing layer may be made of an identical semiconductor material containing a specified metallic element. In this case, the first composition changing layer may be a layer in which a composition proportion of the specified metallic element is continuously changed from the first position to the second position. Further, the second composition changing layer may be a layer in which the composition proportion of the specified metallic element is continuously changed from the third position to the fourth position.

The first composition changing layer may be a layer having a refractive index continuously changed from the first position to the second position. In this case, the second composition changing layer may be a layer having a refractive index continuously changed from the third position to the fourth position.

The first composition changing layer may be a layer in which a bandgap is continuously changed from the first position to the second position. In this case, the second composition changing layer may be a layer in which a bandgap is continuously changed from the third position to the fourth position.

The light-emitting device may further include at least one other layer. In this case, the first composition changing layer, the interlayer, and the second composition changing layer may be formed such that the composition of the interlayer is different from a composition of the at least one other layer.

The second position and the third position may be set such that the composition of the interlayer is different from the composition of the at least one other layer.

### Advantageous Effects of Invention

As described above, the present technology makes it possible to perform a nondestructive, efficient test. Note that the effect described here is not necessarily limitative, and any of the effects described in the present disclosure may be provided.

### BRIEF DESCRIPTION OF DRAWINGS

FIG. 1 schematically illustrates an example of a cross-sectional configuration of a semiconductor laser device according to an embodiment.

FIG. 2 is a graph illustrating a specific example of a stacking structure of the semiconductor laser device.

FIG. 3 is a schematic graph illustrating a relationship between a position in a thickness direction of the stacking structure, and a bandgap.

FIG. 4 is a graph illustrating a result of simulating a relationship between a diffraction angle and the X-ray intensity when the stacking structure of the semiconductor laser device is evaluated by X-ray diffraction (XRD).

FIG. 5 is a graph illustrating a specific example of a stacking structure of a semiconductor laser device of a comparative example.

FIG. 6 is a graph illustrating a result of simulating a relationship between a diffraction angle and the X-ray intensity when the stacking structure of the semiconductor laser device is evaluated by X-ray diffraction.

### MODE(S) FOR CARRYING OUT THE INVENTION

Embodiments according to the present technology will now be described below with reference to the drawings.

[Semiconductor Laser Device]

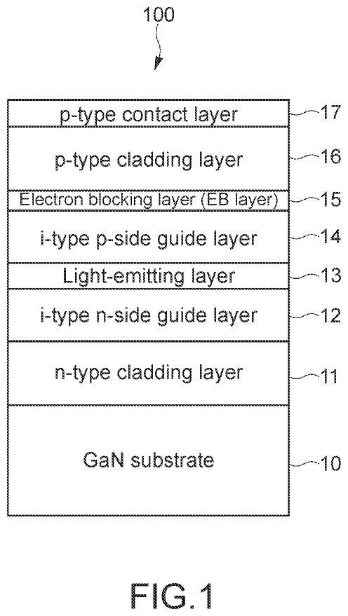

FIG. 1 schematically illustrates an example of a cross-sectional configuration of a semiconductor laser device according to an embodiment of the present technology. In FIG. 1, hatching that represents a cross section is omitted.

In the present embodiment, a nitride semiconductor laser is configured as a semiconductor laser device 100. The nitride semiconductor is a semiconductor that contains a nitrogen (N) element, and is a compound semiconductor that contains a metallic element such as aluminum (Al), gallium (Ga), and indium (In).

The semiconductor laser device 100 includes a substrate 10, an n-type cladding layer 11, an n-side guide layer 12, and a light-emitting layer 13. The semiconductor laser device 100 further includes a p-side guide layer 14, an electron blocking layer (EB layer) 15, a p-type cladding layer 16, and a p-type contact layer 17.

As illustrated in FIG. 1, the semiconductor laser device 100 has a stacking structure in which the substrate 10, the n-type cladding layer 11, the n-side guide layer 12, the light-emitting layer 13, the p-side guide layer 14, the electron blocking layer (EB layer) 15, the p-type cladding layer 16, and the p-type contact layer 17 are stacked in this order.

In the present embodiment, a GaN substrate is used as the substrate 10. Without being limited thereto, a substrate made of another material such as GaN, AlN, Al₂O₃ (sapphire), SiC, Si, or ZrO may be used.

The crystal plane of a primary surface of the substrate 10 may be any of a polar plane, a semipolar plane, and a nonpolar plane. Specifically, the polar plane can be represented by, for example, {0, 0, 0, 1} or {0, 0, 0, −1} using a plane index. The semipolar plane can be represented by, for example, {2, 0, −2, 1}, {1, 0, −1, 1}, {2, 0, −2, −1}, or {1, 0, −1, −1}. The nonpolar plane can be represented by, for example, {1, 1, −2, 0}, or {1, −1, 0, 0}. In the present embodiment, the crystal plane of the primary surface is a {0, 0, 0, 1} plane that is a polar plane.

The n-type cladding layer 11 is formed on the primary surface of the substrate 10. For example, a layer having an n-type conductivity, such as a GaN layer, an AlGaN layer, or an AlGaInN layer, is formed as the n-type cladding layer 11. Alternatively, a layer obtained by stacking a plurality of layers from among those layers may be formed as the n-type cladding layer 11.

For example, Si may be used as a dopant for obtaining an n-type conductivity. For example, the thickness of the n-type cladding layer 11 can be designed in a range of from 500 nm to 3000 nm. Of course, the thickness of the n-type cladding layer 11 is not limited to being in this range, and may be designed discretionarily.

The n-side guide layer 12 is formed on the n-type cladding layer 11. For example, an undoped layer such as a GaN layer, a GaInN layer, or an AlGaInN layer is formed as the n-side guide layer 12. Alternatively, a layer obtained by stacking a plurality of layers from among those layers may be formed as the n-side guide layer 12.

In the present embodiment, the i-type n-side guide layer 12 is formed, but the n-side guide layer 12 may be formed to have an n-type conductivity. For example, Si may be used as a dopant for obtaining an n-type conductivity. For example, the thickness of the n-side guide layer 12 can be designed in a range of from 10 nm to 500 nm. Of course, the thickness of the n-side guide layer 12 is not limited to being in this range, and may be designed discretionarily.

The light-emitting layer (active layer) 13 is formed on the n-side guide layer 12. The light-emitting layer 13 has a quantum well structure, and is formed by stacking a well layer and a barrier layer. For example, a layer having an n-type conductivity, such as an InGaN layer, is formed as the well layer. For example, Si may be used as a dopant for obtaining an n-type conductivity. Note that the well layer may be an undoped layer. For example, the thickness of the well layer can be designed in a range of from 1 nm to 20 nm. Of course, the thickness of the well layer is not limited to being in this range, and may be designed discretionarily.

For example, a layer having an n-type conductivity, such as a GaN layer, an InGaN layer, an AlGaN layer, or an AlGaInN layer, is formed as the barrier layer. For example, Si may be used as a dopant for obtaining an n-type conductivity. Note that the barrier layer may be an undoped layer. For example, the thickness of the barrier layer can be designed in a range of from 1 nm to 100 nm. Of course, the thickness of the barrier layer is not limited to being in this range, and may be designed discretionarily.

Note that the barrier layer is set to have a bandgap not less than a largest bandgap in the well layer. The well layer and the barrier layer are alternately provided, where the number of well layers is an integer that satisfies m≥1. In the present embodiment, m=2. Of course, the present technology is not limited to such a configuration.

For example, a photon wavelength generated by the light-emitting layer 13 is in a range of from 430 nm to 550 nm. Of course, the photon wavelength is not limited to being in this range.

The p-side guide layer 14 is formed on the light-emitting layer 13. For example, un undoped layer such as a GaN layer, an InGaN layer, or an AlGaInN layer is formed as the p-side guide layer 14. Alternatively, a layer obtained by stacking a plurality of layers from among those layers may be formed as the p-side guide layer 14.

In the present embodiment, the i-type p-side guide layer 14 is formed, but the p-side guide layer 14 may be formed to have a p-type conductivity. For example, Mg may be used as a dopant for obtaining a p-type conductivity. For example, the thickness of the p-side guide layer 14 can be designed in a range of from 100 nm to 1000 nm. Of course, the thickness of the p-side guide layer 14 is not limited to being in this range, and may be designed discretionarily.

In the present embodiment, the p-side guide layer 14 is configured as a compositional gradient layer that includes a monitor layer. The compositional gradient layer including a monitor layer will be described in detail later.

The electron blocking layer (EB layer) 15 is formed on the p-side guide layer 14. For example, a layer having a p-type conductivity, such as a GaN layer, an AlGaN layer, or an AlGaInN layer, is formed as the EB layer 15. Alternatively, a layer obtained by stacking a plurality of layers from among those layers may be formed as the EB layer 15.

For example, Mg may be used as a dopant for obtaining a p-type conductivity. For example, the thickness of the EB layer 15 can be designed in a range of from 3 nm to 50 nm. Of course, the thickness of the EB layer 15 is not limited to being in this range, and may be designed discretionarily.

The p-type cladding layer 16 is formed on the EB layer 15. For example, a layer having a p-type conductivity, such as a GaN layer, an AlGaN layer, or an AlGaInN layer, is formed as the p-type cladding layer 16. Alternatively, a layer obtained by stacking a plurality of layers from among those layers may be formed as the p-type cladding layer 16.

For example, Mg may be used as a dopant for obtaining a p-type conductivity. For example, the thickness of the p-type cladding layer 16 can be designed in a range of from 1 nm to 300 nm. Of course, the thickness of the p-type cladding layer 16 is not limited to being in this range, and may be designed discretionarily.

The p-type contact layer 17 is formed on the p-type cladding layer 16. For example, a layer having a p-type conductivity, such as a GaN layer, an AlGaN layer, or an AlGaInN layer, is formed as the p-type contact layer 17. Alternatively, a layer obtained by stacking a plurality of layers from among those layers may be formed as the p-type contact layer 17.

For example, Mg may be used as a dopant for obtaining a p-type conductivity. For example, the thickness of the p-type contact layer 17 can be designed in a range of from 1 nm to 300 nm. Of course, the thickness of the p-type contact layer 17 is not limited to being in this range, and may be designed discretionarily.

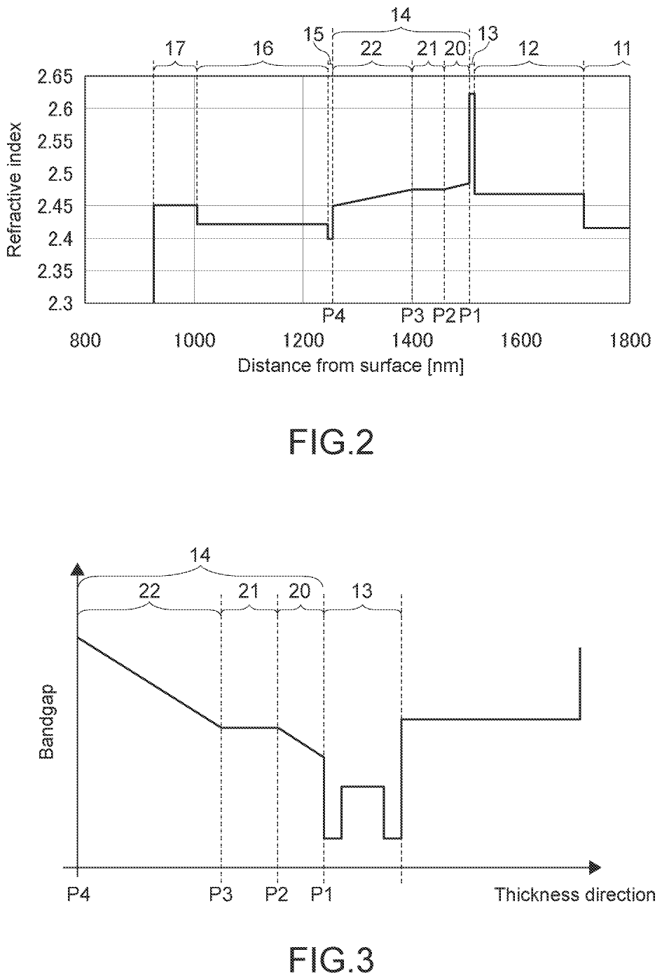

FIG. 2 is a graph illustrating a specific example of the stacking structure of the semiconductor laser device 100. The horizontal axis of the graph represents a distance (nm) from the surface of the semiconductor laser device 100 (a surface when a portion up to, for example, a transparent conductive film and an electrode is included), and corresponds to a position in a thickness direction of the stacking structure. The vertical axis of the graph represents a refractive index. Further, a numerical reference for each layer illustrated in FIG. 1 is given in an upper portion of the graph.

The stacking structure illustrated in FIG. 2 has a configuration indicated below.

n-type cladding layer 11: an AlGaN layer that has an Al compositional proportion of 6% and a thickness of 1000 nm

n-side guide layer 12: a GaInN layer that has an In compositional proportion of 2% and a thickness of 200 nm

light-emitting layer 13: a GaInN stacking structure that includes two well layers 2 and a barrier layer and has an emission wavelength of 450 nm

p-side guide layer 14: a compositional gradient layer that includes a monitor layer (described in detail later)

EB layer 15: an AlGaN layer that has an Al compositional proportion of 10% and a thickness of 10 nm

p-type cladding layer 16: an AlGaN layer that has an Al compositional proportion of 5.5% and a thickness of 250 nm

p-type contact layer: a GaN layer of a thickness of 80 nm

The p-side guide layer 14 includes a first composition changing layer 20, a monitor layer 21, and a second composition changing layer 22. The first composition changing layer 20 is a layer having a composition continuously changed at a first change rate from a first position to a second position in the thickness direction.

In the present embodiment, a GaInN compositional gradient layer that has a thickness of 50 nm and in which the In compositional proportion is changed from 4% to 3% in a graded manner from the light-emitting layer 13 to the surface, is formed as the first composition changing layer 20. A position of a boundary between the p-side guide layer 14 and the light-emitting layer 13 is the first position P1. Further, a position at which an In compositional proportion is 3% is the second position P2.

The monitor layer 21 is formed between the second position P2 and a third position P3 in the thickness direction, and has a composition identical to a composition of the first composition changing layer 20 at the second position P2. In the present embodiment, a GaInN monitor layer having an In compositional proportion of 3% and a thickness of 50 nm is formed as the monitor layer 21. Thus, a position displaced 50 nm toward the surface from the second position P2 is the third position P3.

In the present embodiment, the monitor layer 21 serves as an interlayer in which the composition is constant. The monitor layer 21 may also be referred to as a constant composition layer.

Note that, in the configuration of the monitor layer 21, expressions such as “composition identical to a composition of” and “composition is constant” may respectively include not only expressions such as “composition exactly identical to a composition of” and “composition is quite constant” in concept, but also expressions such as “composition substantially identical to a composition of” and “composition is substantially constant” in concept.

For example, in the present embodiment, the “composition identical to the composition of the first composition changing layer 20 at the second position P2” may include a case in which the In compositional proportion is in a range of +/−0.1% with respect to the In compositional proportion of the first composition changing layer 20 at the second position P2. For example, when the In compositional proportion of the first composition changing layer 20 at the second position P2 is 3%, a layer in which the In compositional proportion is in a range of 2.9% to 3.1%, is included in a layer that has a “composition identical to the composition of the first composition changing layer 20 at the second position P2”.

Further, the “constant composition layer in which the composition is constant” may include a layer in which a change in In compositional proportion is within +/−0.1%. For example, the “constant composition layer in which the In compositional proportion is constant at 3%” may include a layer in which the change range of the In compositional proportion is a range of from of 2.9% to 3.1%.

Note that a specific numerical range used to define the “composition substantially identical to a composition of” and the “composition is substantially constant” is not limited to the range of +/−0.1%. The specific range used to define the “composition substantially identical to a composition of” and the “composition is substantially constant” may be determined such that an effect provided by the present technology and described later is obtained, the effect being an effect of being able to test the semiconductor laser device 100 non-destructively and efficiently.

The second composition changing layer 22 is a layer having a composition continuously changed at a second change rate from the third position P3 to a fourth position P4 in the thickness direction, the second composition changing layer 22 having, at the third position P, a composition that is identical to a composition of the monitor layer 21.

In the present embodiment, a GaInN compositional gradient layer that has a thickness of 150 nm and in which the In compositional proportion is changed from 3% to 0% in a graded manner from the third position P3 to the surface, is formed as the second composition changing layer 22. A position of a boundary between the p-side guide layer 14 and the EB layer 15 is the fourth position P4.

Note that, in the present embodiment, the change rate for the In compositional proportion in the first composition changing layer 20 and the change rate for the In compositional proportion in the second composition changing layer 22 are identical to each other. In other words, the first change rate and the second change rate described above are identical to each other.

Thus, the p-side guide layer 14 formed from the first position P1 to the fourth position P4 can also be referred to as a compositional gradient layer in which the monitor layer 21 having a constant composition is formed in the middle portion (situated between the second position P2 and the third position P3). Further, the configuration of the p-side guide layer 14 can also be referred to as a graded index (GRIN) structure that includes the monitor layer 21.

In the present embodiment, the first composition changing layer 20, the monitor layer 21, and the second composition changing layer 22 are made of an identical semiconductor material (GaInN) containing a specified metallic element (In). The first composition changing layer 20 is a layer in which the composition proportion of the specified metallic element (In) is continuously changed from the first position P1 to the second position P2. The monitor layer 21 is a layer in which the composition proportion of the specified metallic element (In) is constant. Further, the second composition changing layer 22 is a layer in which the composition proportion of the specified metallic element (In) is continuously changed from the third position P3 to the fourth position P4.

As illustrated in FIG. 2, when there is a decrease in the composition proportion of In, the refractive index is decreased. When there is an increase in the composition proportion of In, the refractive index is decreased. Thus, in the first composition changing layer 20, the refractive index is continuously changed from the first position P1 to the second position P2. In the monitor layer 21, the refractive index is constant. In the second composition changing layer 22, the refractive index is continuously changed from the third position P3 to the fourth position P4. Thus, in a region other than the monitor layer 21 in the p-side guide layer 14, the refractive index is continuously increased from the EB layer 15 to the light-emitting layer 13.

FIG. 3 is a schematic graph illustrating a relationship between a position in the thickness direction of the stacking structure, and a bandgap. FIG. 3 schematically illustrates a thickness of the light-emitting layer 13 in an enlarged manner.

In each layer, the bandgap is increased as the refractive index is decreased. Further, the bandgap is reduced as the refractive index is increased. Thus, as illustrated in FIG. 3, the bandgap is continuously changed from the first position P1 to the second position P2 in the first composition changing layer 20. The bandgap is constant in the monitor layer 21. The bandgap is continuously changed from the third position P3 to the fourth position P4 in the second composition changing layer 22. Therefore, in the region other than the monitor layer 21 in the p-side guide layer 14, the bandgap is continuously reduced from the EB layer 15 to the light-emitting layer 13.

In the region other than the monitor layer 21, the refractive index is increased and the bandgap is reduced toward the light-emitting layer 13. This makes it possible to confine light and a carrier to the light-emitting layer 13. This results in a higher output of a semiconductor laser and in a higher efficiency in the semiconductor laser. In other words, in the present embodiment, the formation of a compositional gradient layer (a GRIN structure) including the monitor layer 21 results in improving the laser characteristics.

Metalorganic chemical vapor deposition (MOCVD) is an example of a method for forming a compositional gradient layer that includes the monitor layer 21. It is possible to form the monitor layer 21 at a desired position in a compositional gradient layer by performing a flow control and a time control with respect to source gas using, for example, a massflow controller. Of course, another film forming technique or the like may be used.

For example, when the first position is represented by 0 and the fourth position is represented by 1 in the thickness direction, the monitor layer 21 can be formed at any position in a range of from 0.1 to 0.9. Further, the thickness of the monitor layer 21 can be set as appropriate.

Typically, the monitor layer 21 is formed such that it is possible to monitor the monitor layer 21 upon analysis such as X-ray diffraction analysis. For example, the monitor layer 21 is configured to have a composition different from all of the compositions of the other layers of the semiconductor laser device 100. Consequently, for example, the monitor layer 21 is formed to have a composition different from the composition of at least one layer from among the other layers such as the n-side guide layer 12 illustrated in FIG. 1. This makes it possible to monitor a state and the like of the monitor layer 21.

It is assumed that, for example, the p-side guide layer 14 is continuously formed using, for example, MOCVD. In this case, the composition of the monitor layer 21 is defined by a position (the second position P2 and the third position P3) at which the monitor layer 21 is formed. Thus, the second position P2 and the third position P3 are set such that the composition of the monitor layer 21 is different from all of the compositions of the other layers. In other words, the second position P2 and the third position P3 are set as appropriate such that the monitor layer 21 has a desired composition.

The thickness of the monitor layer 21 is also set such that the monitor layer 21 can be monitored. The monitor layer 21 is formed to have a thickness of, for example, not less than 20 nm. This makes it possible to sufficiently monitor the monitor layer 21. Of course, the thickness is not limited to this, and a thickness of not greater than 20 nm may be adopted.

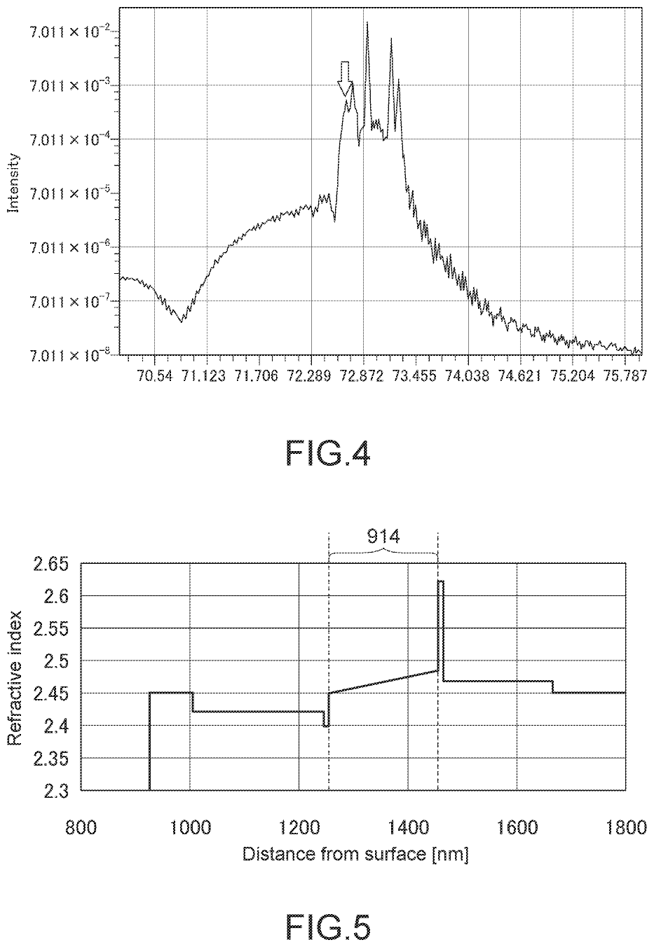

FIG. 4 is a graph illustrating a result of simulating a relationship between a diffraction angle and the X-ray intensity when the stacking structure of the semiconductor laser device is evaluated by X-ray diffraction (XRD).

A signal that indicates an In compositional proportion of 3% in the monitor layer 21 and clearly reaches a peak is confirmed at a position indicated by an arrow. This shows that it is possible to evaluate the In compositional proportion in the monitor layer 21 using a waveform of X-ray diffraction. It is clear, from the setting of a growth time, at which position in a compositional gradient layer the monitor layer 21 is situated. Thus, the evaluation of the In compositional proportion in the monitor layer 21 makes it possible to determine the quality of the p-side guide layer 14 that is a compositional gradient layer.

For example, when it is not confirmed that the signal indicating an In compositional proportion of 3% clearly reaches a peak, this shows that the monitor layer 21 is not properly formed. Thus, a compositional gradient layer including the monitor layer 21 is also not properly formed. For example, when a peak of a composition proportion other than the In compositional proportion of 3% is confirmed, the compositional gradient layer is also not properly formed.

As described above, it is possible to evaluate the entity of a compositional gradient layer on the basis of a result of monitoring the monitor layer 21. This results in being able to test the semiconductor laser device 100 including a compositional gradient layer non-destructively and efficiently.

Further, it is also possible to measure the thickness of the monitor layer 21 by, for example, X-ray reflectometry (XRR). It is also possible to evaluate the entirety of a compositional gradient layer on the basis of the measured thickness of the monitor layer 21. For example, when the thickness of the monitor layer 21 is too large or too small, the compositional gradient layer is not properly formed.

FIG. 5 is a graph illustrating a specific example of a stacking structure of a semiconductor laser device of a comparative example. This semiconductor laser device is different from the semiconductor laser device 100 illustrated in FIG. 2 in including a p-side guide layer 914 having a different configuration, whereas it has a configuration similar to the configuration of the semiconductor laser device 100 illustrated in FIG. 2 with respect to the other layers.

A GaInN compositional gradient layer that has a thickness of 200 nm and in which the In compositional proportion is changed from 4% to 0% in a graded manner from a light-emitting layer to the surface, is formed as the p-side guide layer 914. In other words, in the semiconductor laser device of the comparative example, a monitor layer is not formed in a compositional gradient layer.

The formation of a compositional gradient layer as the p-side guide layer 914 makes it possible to confine light and a carrier to the light-emitting layer. This results in a higher output of a semiconductor laser and in a higher efficiency in the semiconductor laser.

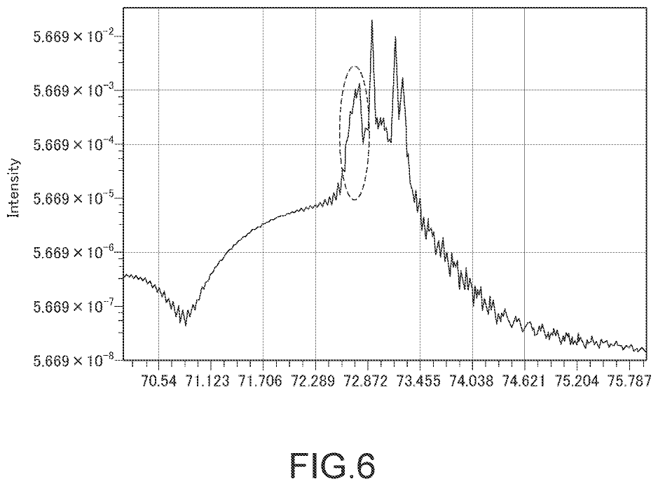

FIG. 6 is a graph illustrating a result of simulating a relationship between a diffraction angle and the X-ray intensity when the stacking structure of the semiconductor laser device is evaluated by X-ray diffraction.

Since the In compositional proportion is continuously changed in the entirety of the p-side guide layer 914, only a broad signal is obtained (a small convex portion indicates a fringe (an interference fringe)), as indicated with a region surrounded by a dashed circle illustrated in FIG. 6. Thus, the quality of the p-side guide layer 914 that is a compositional gradient layer is not allowed to be evaluated using, for example, an X-ray diffraction evaluation. This results in difficulty in testing the semiconductor laser device non-destructively and efficiently.

As described above, in the semiconductor laser device 100 according to the present embodiment, the monitor layer 21 having a constant composition is formed from the first position P1 to the fourth position P4 in the thickness direction. Consequently, for example, the use of X-ray diffraction or the like makes it possible to test the semiconductor laser device 100 non-destructively and efficiently.

In recent years, a light source using a semiconductor laser device has been increasingly put into commercial use due to blue and green lasers using a GaN semiconductor having been put into commercial use, and a semiconductor laser source with a higher output and a higher efficiency is increasingly expected. The introduction of a compositional gradient layer in which the bandgap energy is reduced and the refractive index is increased toward a light-emitting layer, is effective in increasing the efficiency in a semiconductor laser device. A structure including a compositional gradient layer is generally called a GRIN structure, and makes it possible to confine light and a carrier to a light-emitting layer.

However, the refractive index of a compositional gradient layer is continuously changed, and this results in being unable to perform a non-destructive test with respect to the quality of the compositional gradient layer using, for example, X-ray diffraction. There is a need to break a wafer and to evaluate the cross-section obtained by the breaking, using an analysis method such as a transmission electron microscope (TEM) or secondary ion mass spectrometry (SIMS). Thus, it is difficult to manage the quality of a wafer itself used to produce a semiconductor laser device.

In the semiconductor laser device 100 according to the present embodiment, the monitor layer 21 having a uniform composition is formed in a middle portion of a compositional gradient layer. This makes it possible to non-destructively monitor a composition and the crystallinity of the monitor layer 21 by evaluating a substrate using, for example, X-ray diffraction. It is possible to determine the quality of the compositional gradient layer on the basis of a result of the monitoring. In other words, the management of the monitor layer 21 makes it possible to indirectly manage the quality of the compositional gradient layer.

Note that a method other than X-ray analysis can be adopted as a method for analyzing a semiconductor laser device non-destructively. For example, the present technology is also effective when an analysis using, for example, an ellipsometer is performed. In other words, the formation of the monitor layer 21 makes it possible to indirectly determine the quality of a compositional gradient layer.

### Other Embodiments

The present technology is not limited to the embodiments described above, and can achieve various other embodiments.

A nitride semiconductor laser has been described above as an example of the semiconductor laser device 100. Without being limited thereto, the present technology is also applicable to other types of semiconductor laser devices. Further, the present technology is also applicable to a light-emitting device other than a semiconductor laser device. Examples of such a light-emitting device may include a light-emitting diode (LED), a superluminescent diode (SLD), and a semiconductor optical amplifier.

In the description above, the p-side guide layer 14 is configured as a compositional gradient layer including a monitor layer. Without being limited thereto, for example, an n-side guide layer or the like may be configured as a compositional gradient layer including a monitor layer. Further, guide layers on both the p-side and the n-side may be configured as compositional gradient layers each including a monitor layer. In this case, the respective monitor layers are designed to have different compositions. Of course, a layer other than a guide layer may be configured as a compositional gradient layer including a monitor layer.

The example in which the first change rate that is a change rate of a composition of the first composition changing layer 20, and the second change rate that is a change rate of a composition of the second composition changing layer 22 are identical to each other, has been described above. Without being limited thereto, the present technology is also applicable when the first change rate and the second change rate are different from each other.

The respective configurations of semiconductor laser device, the stacking structure, and the like, as well as the method for analyzing the semiconductor laser device described with reference to the respective figures are merely embodiments, and any modifications may be made thereto without departing from the spirit of the present technology. In other words, for example, any other configurations and any analysis methods for purpose of practicing the present technology may be adopted.

In the present disclosure, expressions such as “constant”, “uniform”, “identical”, and “the same” may respectively include not only expressions such as “quite constant”, “exactly uniform”, “exactly identical”, and “exactly the same” in concept, but also expressions such as “substantially constant”, “substantially uniform”, “substantially identical”, and “substantially the same” in concept. For example, the expressions such as “constant”, “uniform”, “identical”, and “the same” also respectively include specified ranges in concept, with the expressions such as “quite constant”, “exactly uniform”, “exactly identical”, and “exactly the same” being respectively used as references.

At least two of the features of the present technology described above can also be combined. In other words, various features described in the respective embodiments may be combined discretionarily regardless of the embodiments. Further, the various effects described above are not limitative but are merely illustrative, and other effects may be provided.

Note that the present technology may also take the following configurations.

(1) A light-emitting device, including:

a first composition changing layer that has a composition continuously changed at a first change rate from a first position to a second position in a thickness direction of the light-emitting device;

an interlayer that is formed between the second position and a third position in the thickness direction, the interlayer having a composition identical to a composition of the first composition changing layer at the second position; and

a second composition changing layer that has a composition continuously changed at a second change rate from the third position to a fourth position in the thickness direction, the second composition changing layer having, at the third position, a composition identical to the composition of the interlayer.

(2) The light-emitting device according to (1), in which

the first change rate is identical to the second change rate.

(3) The light-emitting device according to (1) or (2), in which

the light-emitting device is configured as a semiconductor laser device.

(4) The light-emitting device according to (3), in which

the first composition changing layer, the interlayer, and the second composition changing layer form a guide layer.

(5) The light-emitting device according to any one of (1) to (4), in which

the interlayer has a thickness of not less than 20 nm.

(6) The light-emitting device according to any one of (1) to (5), in which

when the first position is represented by 0 and the fourth position is represented by 1, the interlayer is formed in a range of from 0.1 to 0.9.

(7) The light-emitting device according to any one of (1) to (6), in which

the first composition changing layer, the interlayer, and the second composition changing layer form a compositional gradient layer having a constant composition between the second position and the third position.

(8) The light-emitting device according to any one of (1) to (7), in which

the first composition changing layer, the interlayer, and the second composition changing layer are made of an identical semiconductor material containing a specified metallic element,

the first composition changing layer is a layer in which a composition proportion of the specified metallic element is continuously changed from the first position to the second position, and

the second composition changing layer is a layer in which the composition proportion of the specified metallic element is continuously changed from the third position to the fourth position.

(9) The light-emitting device according to any one of (1) to (8), in which

the first composition changing layer is a layer having a refractive index continuously changed from the first position to the second position, and

the second composition changing layer is a layer having a refractive index continuously changed from the third position to the fourth position.

(10) The light-emitting device according to any one of (1) to (9), in which

the first composition changing layer is a layer in which a bandgap is continuously changed from the first position to the second position, and

the second composition changing layer is a layer in which a bandgap is continuously changed from the third position to the fourth position.

(11) The light-emitting device according to any one of (1) to (10), further including

at least one other layer, in which

the first composition changing layer, the interlayer, and the second composition changing layer are formed such that the composition of the interlayer is different from a composition of the at least one other layer.

(12) The light-emitting device according to (11), in which

the second position and the third position are set such that the composition of the interlayer is different from the composition of the at least one other layer.

### REFERENCE SIGNS LIST

P1 to P4 first position to fourth position
10 substrate
14 p-side guide layer
20 first composition changing layer
21 monitor layer
22 second composition changing layer
100 semiconductor laser device

1. A light-emitting device, comprising:
a first composition changing layer that has a composition continuously changed at a first change rate from a first position to a second position in a thickness direction of the light-emitting device;
an interlayer that is formed between the second position and a third position in the thickness direction, the interlayer having a composition identical to a composition of the first composition changing layer at the second position; and
a second composition changing layer that has a composition continuously changed at a second change rate from the third position to a fourth position in the thickness direction, the second composition changing layer having, at the third position, a composition identical to the composition of the interlayer.

2. The light-emitting device according to claim 1, wherein
the first change rate is identical to the second change rate.

3. The light-emitting device according to claim 1, wherein
the light-emitting device is configured as a semiconductor laser device.

4. The light-emitting device according to claim 3, wherein
the first composition changing layer, the interlayer, and the second composition changing layer form a guide layer.

5. The light-emitting device according to claim 1, wherein
the interlayer has a thickness of not less than 20 nm.

6. The light-emitting device according to claim 1, wherein
when the first position is represented by 0 and the fourth position is represented by 1, the interlayer is formed in a range of from 0.1 to 0.9.

7. The light-emitting device according to claim 1, wherein
the first composition changing layer, the interlayer, and the second composition changing layer form a compositional gradient layer having a constant composition between the second position and the third position.

8. The light-emitting device according to claim 1, wherein
the first composition changing layer, the interlayer, and the second composition changing layer are made of an identical semiconductor material containing a specified metallic element,
the first composition changing layer is a layer in which a composition proportion of the specified metallic element is continuously changed from the first position to the second position, and
the second composition changing layer is a layer in which the composition proportion of the specified metallic element is continuously changed from the third position to the fourth position.

9. The light-emitting device according to claim 1, wherein
the first composition changing layer is a layer having a refractive index continuously changed from the first position to the second position, and
the second composition changing layer is a layer having a refractive index continuously changed from the third position to the fourth position.

10. The light-emitting device according to claim 1, wherein
the first composition changing layer is a layer in which a bandgap is continuously changed from the first position to the second position, and
the second composition changing layer is a layer in which a bandgap is continuously changed from the third position to the fourth position.

11. The light-emitting device according to claim 1, further comprising
at least one other layer, wherein
the first composition changing layer, the interlayer, and the second composition changing layer are formed such that the composition of the interlayer is different from a composition of the at least one other layer.

12. The light-emitting device according to claim 11, wherein
the second position and the third position are set such that the composition of the interlayer is different from the composition of the at least one other layer.
